(19) United States
(12) Patent Application Publication
(10) Pub. No.: US 2026/0271558 A1
(43) Pub. Date: Sep. 10, 2026

(54) DISPLAY DEVICE AND ELECTRONIC DEVICE INCLUDING THE SAME

(71) Applicant: Samsung Display Co., Ltd., Yongin-si (KR)

(72) Inventors: Dong Hyeon JANG, Yongin-si (KR); Won Se LEE, Yongin-si (KR); Ji Eun LEE, Yongin-si (KR); Min Kyung PARK, Yongin-si (KR); Geun Ho LEE, Yongin-si (KR)

(21) Appl. No.: 19/346,179

(22) Filed: Sep. 30, 2025

(30) Foreign Application Priority Data
Mar. 6, 2025 (KR) 10-2025-0028611
Apr. 21, 2025 (KR) 10-2025-0051622

(51) Int. Cl. H10K 59/131; H10K 59/124

(52) U.S. Cl. CPC H10K 59/131; H10K 59/124

(57) ABSTRACT

A display device includes: a substrate; a circuit layer on the substrate; and a display driving circuit configured to output data signals, wherein the substrate comprises a main region, and a sub-region, the sub-region includes a bending area transformed into a bent shape, and a pad area connected to the bending area and including an open area parallel to the bending area, and an open peripheral area surrounding the open area, the display driving circuit is in the open peripheral area, and the data lines are electrically connected to the display driving circuit through data connection lines each including: a data output line electrically connected to the display driving circuit and in the open peripheral area; a data bending line in the bending area; and a data bridge line in the at least one open area and electrically connected between the data output line and the data bending line.

### CROSS-REFERENCE TO RELATED APPLICATION

The present application claims priority to and the benefit of Korean Patent Application No. 10-2025-0028611, filed on Mar. 6, 2025, in the Korean Intellectual Property Office, and Korean Patent Application No. 10-2025-0051622, filed on Apr. 21, 2025, in the Korean Intellectual Property Office, the entire disclosures of each of which are incorporated herein by reference.

### BACKGROUND

### 1. Field

Aspects of some embodiments of the present disclosure relate to a display device and an electronic device including the same.

### 2. Description of the Related Art

With the advance of information-oriented society, more and more demands are placed on display devices for displaying images in various ways. For example, display devices may be employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays images using light emitting elements, each including a light emitting layer containing an organic light emitting material. As described above, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area at which images are displayed, and a non-display area around the display area. Emission areas emitting light with respective luminances and colors may be arranged in the display area.

The above information disclosed in this Background section is only for enhancement of understanding of the background and therefore the information discussed in this Background section does not necessarily constitute prior art.

### SUMMARY

According to some embodiments, the display device may include a display driving circuit outputting data signals to data lines and located in a sub-region of a substrate.

According to some embodiments, the data lines may be electrically connected to the display driving circuit via data connection lines.

However, in order to reduce the occurrence of a permeation path of oxygen or moisture from the sub-region to the display area through one or more organic insulating layers each containing an organic insulating material, the display device may include at least one open groove that overlaps at least one open area of the sub-region and is formed in one or more organic insulating layers.

In this case, some of the data connection lines overlapping the at least one open groove are not covered with one or more organic insulating layers, and thus may be corroded relatively easily. Accordingly, there is a problem that limits the improvement in the lifespan of the display device.

In view of the foregoing, aspects of some embodiments of the present disclosure include a display device capable of relatively improving the lifespan by including at least one open groove for reducing the permeation path of contaminants such as oxygen or moisture and preventing or reducing corrosion of data connection lines.

However, aspects of some embodiments of the present disclosure are not restricted to those set forth herein. The above and other aspects of some embodiments of the present disclosure will become more apparent to one of ordinary skill in the art to which the present disclosure pertains by referencing the detailed description of the present disclosure given below.

According to some embodiments of the present disclosure, there is provided a display device comprises a substrate; a circuit layer located on the substrate; and a display driving circuit outputting data signals of data lines of the circuit layer. The substrate comprises a main region, and a sub-region protruding from a part of an edge of the main region. According to some embodiments, the sub-region comprises a bending area adjacent to the main region and transformed into a bent shape, and a pad area connected to one side of the bending area. According to some embodiments, the pad area comprises at least one open area located adjacent to and parallel to the bending area, and an open peripheral area surrounding the at least one open area. The display driving circuit is located in the open peripheral area. According to some embodiments, the data lines are electrically connected to the display driving circuit through data connection lines. Each of the data connection lines comprises a data output line electrically connected to the display driving circuit and located in the open peripheral area; a data bending line located in the bending area; and a data bridge line located in the at least one open area and electrically connected between the data output line and the data bending line.

According to some embodiments, the circuit layer comprises a first gate insulating layer located on the substrate; a first gate conductive layer located on the first gate insulating layer; a second gate insulating layer covering the first gate conductive layer; a second gate conductive layer located on the second gate insulating layer; an interlayer insulating layer covering the second gate conductive layer; and a first source-drain conductive layer located on the interlayer insulating layer. According to some embodiments, the data output line of each of the data connection lines is located in the first source-drain conductive layer. According to some embodiments, the data bridge line of each of the data connection lines is located in the first gate conductive layer or the second gate conductive layer.

According to some embodiments, the circuit layer further comprises a first planarization layer covering the first source-drain conductive layer; a second source-drain conductive layer located on the first planarization layer; a second planarization layer covering the second source-drain conductive layer; and at least one open groove overlapping the at least one open area and formed in the first planarization layer and the second planarization layer.

According to some embodiments, each of the second gate insulating layer and the interlayer insulating layer contains an inorganic insulating material. According to some embodiments, the interlayer insulating layer is exposed through the at least one open groove. According to some embodiments, the data bridge line of each of the data connection lines is covered with the second gate insulating layer or the interlayer insulating layer.

According to some embodiments, the data bridge line of each of the data connection lines is located in the first gate conductive layer and covered with the second gate insulating layer and the interlayer insulating layer.

According to some embodiments, the circuit layer further comprises a passivation layer covering the interlayer insulating layer and the data output lines of the data connection lines. According to some embodiments, the first planarization layer is located on the passivation layer. According to some embodiments, each of the second gate insulating layer, the interlayer insulating layer, and the passivation layer contains an inorganic insulating material. According to some embodiments, the passivation layer is exposed through the at least one open groove. According to some embodiments, the data bridge line of each of the data connection lines is covered with the passivation layer and at least one of the second gate insulating layer or the interlayer insulating layer.

According to some embodiments, the main region comprises a display area in which emission areas are arranged, and a non-display area located around the display area. According to some embodiments, the data lines are located in the display area. According to some embodiments, each of the data connection lines further comprises a data supply line located in the non-display area and electrically connected to the data bending line. According to some embodiments, the data supply lines of the data connection lines are electrically connected to the data lines.

According to some embodiments, the display device further comprises an element layer located on the circuit layer; an encapsulation layer covering the element layer; and a touch sensor layer located on the encapsulation layer. According to some embodiments, the element layer comprises first electrodes located in the emission areas; a pixel defining layer located in a non-emission area between the emission areas and covering edges of the first electrodes; light emitting layers located on the first electrodes; and a second electrode located on the pixel defining layer and the light emitting layers. According to some embodiments, the touch sensor layer further comprises a touch buffer layer located on the encapsulation layer; a touch interlayer insulating layer covering a first touch conductive layer on the touch buffer layer; and a touch planarization layer covering a second touch conductive layer on the touch interlayer insulating layer. According to some embodiments, the pixel defining layer extends to the sub-region. According to some embodiments, the at least one open groove is further formed in the pixel defining layer.

According to some embodiments, the display device further comprises constant voltage connection lines located in the open peripheral area, the bending area and the non-display area and transmitting a constant voltage. According to some embodiments, some of the data output lines of the data connection lines overlap the constant voltage connection lines in a thickness direction of the substrate.

According to some embodiments, the display device further comprises dummy output lines located in the open peripheral area and arranged between the data output lines. According to some embodiments, the dummy output lines are located in the first source-drain conductive layer and spaced apart from the bending area and the at least one open area and overlap the constant voltage connection lines in the thickness direction of the substrate.

According to some embodiments, the constant voltage connection lines comprise a first power connection line transmitting the first power; and a second power connection line transmitting a second power lower than the first power.

According to an aspect of the present disclosure, there is provided an electronic device comprises a display device displaying an image; a memory storing an application; a processor executing the application and transmitting an image data signal and an input control signal to the display device; and a power module transmitting power to the display device. According to some embodiments, the display device comprises a substrate; a circuit layer located on the substrate; and a display driving circuit outputting data signals of data lines of the circuit layer. According to some embodiments, the substrate comprises a main region, and a sub-region protruding from a part of an edge of the main region. According to some embodiments, the sub-region comprises a bending area adjacent to the main region and transformed into a bent shape, and a pad area connected to one side of the bending area. According to some embodiments, the pad area comprises at least one open area located adjacent to and parallel to the bending area, and an open peripheral area surrounding the at least one open area. According to some embodiments, the display driving circuit is located in the open peripheral area. According to some embodiments, the data lines are electrically connected to the display driving circuit through data connection lines. According to some embodiments, each of the data connection lines comprises a data output line electrically connected to the display driving circuit and located in the open peripheral area; a data bending line located in the bending area; and a data bridge line located in the at least one open area and electrically connected between the data output line and the data bending line.

According to some embodiments, the circuit layer comprises a first gate insulating layer located on the substrate; a first gate conductive layer located on the first gate insulating layer; a second gate insulating layer covering the first gate conductive layer; a second gate conductive layer located on the second gate insulating layer; an interlayer insulating layer covering the second gate conductive layer; a first source-drain conductive layer located on the interlayer insulating layer. A first planarization layer covering the first source-drain conductive layer; a second source-drain conductive layer located on the first planarization layer; a second planarization layer covering the second source-drain conductive layer; and at least one open groove overlapping the at least one open area and formed in the first planarization layer and the second planarization layer.

According to some embodiments, each of the second gate insulating layer and the interlayer insulating layer contains an inorganic insulating material. According to some embodiments, the interlayer insulating layer is exposed through the at least one open groove. According to some embodiments, the data output line of each of the data connection lines is located in the first source-drain conductive layer. According to some embodiments, the data bridge line of each of the data connection lines is located in the first gate conductive layer or the second gate conductive layer and covered with the second gate insulating layer or the interlayer insulating layer.

According to some embodiments, each of the second gate insulating layer and the interlayer insulating layer contains an inorganic insulating material. According to some embodiments, the interlayer insulating layer is exposed through the at least one open groove. According to some embodiments, the data output line of each of the data connection lines is located in the first source-drain conductive layer. According to some embodiments, the data bridge line of each of the data connection lines is located in the first gate conductive layer and covered with the second gate insulating layer or the interlayer insulating layer.

According to some embodiments, the circuit layer further comprises a passivation layer covering the interlayer insulating layer and the data output lines of the data connection lines. According to some embodiments, the first planarization layer is located on the passivation layer. According to some embodiments, each of the second gate insulating layer, the interlayer insulating layer, and the passivation layer contains an inorganic insulating material. According to some embodiments, the passivation layer is exposed through the at least one open groove. According to some embodiments, the data bridge line of each of the data connection lines is covered with the passivation layer and at least one of the second gate insulating layer or the interlayer insulating layer.

According to some embodiments, the main region comprises a display area in which emission areas are arranged, and a non-display area located around the display area. According to some embodiments, the data lines are located in the display area. According to some embodiments, each of the data connection lines further comprises a data supply line located in the non-display area and electrically connected to the data bending line. According to some embodiments, the data supply lines of the data connection lines are electrically connected to the data lines.

According to some embodiments, the display device further comprises an element layer located on the circuit layer; an encapsulation layer covering the element layer; and a touch sensor layer located on the encapsulation layer. According to some embodiments, the element layer comprises first electrodes located in the emission areas; a pixel defining layer located in a non-emission area between the emission areas and covering edges of the first electrodes; light emitting layers located on the first electrodes; and a second electrode located on the pixel defining layer and the light emitting layers. According to some embodiments, the touch sensor layer further comprises a touch buffer layer located on the encapsulation layer; a touch interlayer insulating layer covering a first touch conductive layer on the touch buffer layer; and a touch planarization layer covering a second touch conductive layer on the touch interlayer insulating layer. According to some embodiments, the pixel defining layer extends to the sub-region. The at least one open groove is further formed in the pixel defining layer.

According to some embodiments, the display device further comprises constant voltage connection lines located in the open peripheral area, the bending area and the non-display area and transmitting a constant voltage. According to some embodiments, some of the data output lines of the data connection lines overlap the constant voltage connection lines in a thickness direction of the substrate.

According to some embodiments, the display device further comprises dummy output lines arranged between the data output lines. According to some embodiments, the dummy output lines are located in the first source-drain conductive layer and spaced apart from the bending area and the at least one open area and overlap the constant voltage connection lines in the thickness direction of the substrate.

According to some embodiments, a display device according to some embodiments may include a circuit layer located on a substrate, and a display driving circuit that outputs data signals of data lines of the circuit layer.

According to some embodiments, the substrate may include a main region and a sub-region protruding from a part of an edge of the main region.

According to some embodiments, the sub-region may include a bending area adjacent to the main region and transformed into a bending shape, and a pad area connected to one side of the bending area.

According to some embodiments, the pad area may include at least one open area adjacent to and parallel to the bending area, and an open peripheral area excluding the at least one open area.

According to some embodiments, the display driving circuit may be mounted on the open peripheral area.

According to some embodiments, the data lines may be electrically connected to the display driving circuit via data connection lines.

According to some embodiments, each of the data connection lines may include a data output line electrically connected to the display driving circuit and located in the open peripheral area, a data bending line located in the bending area, and a data bridge line located in the at least one open area and electrically connected between the data output line and the data bending line.

According to some embodiments, the data bridge line may be located in the first gate conductive layer or the second gate conductive layer and covered with the second gate insulating layer or the interlayer insulating layer.

Thus, according to some embodiments, because a data output line located in a first source-drain conductive layer having a relatively low resistance is not directly electrically connected to a data bending line, a part of the data output line may not overlap at least one open area.

Further, according to some embodiments, because a data bridge line of the data connection line overlapping the at least one open area is covered with a second gate insulating layer or an interlayer insulating layer, a corrosion defect of the data bridge line due to the at least one open groove overlapping the at least one open area may be delayed, prevented, or reduced.

Accordingly, the lifespan of a display device according to some embodiments and an electronic device including the same may be relatively improved.

It should be noted that the characteristics of embodiments according to the present disclosure are not limited to those described above and other characteristics of embodiments according to the present disclosure will be apparent to those skilled in the art from the following descriptions.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view showing an electronic device according to some embodiments;

FIG. 2 is an exploded perspective view of the electronic device shown in FIG. 1;

FIG. 3 is a plan view illustrating the display device of FIG. 2;

FIG. 4 is a cross-sectional view taken along the line A-A′ of FIG. 3;

FIG. 5 is a plan view illustrating the substrate of FIG. 4 according to some embodiments;

FIG. 6 is a schematic diagram showing part B of FIG. 5;

FIG. 7 is a block diagram illustrating a display device according to some embodiments;

FIG. 8 is an equivalent circuit diagram showing the light emitting pixel driver of FIG. 7 according to some embodiments;

FIG. 9 is a plan view illustrating the touch sensor layer of FIG. 4 according to some embodiments;

FIG. 10 is an enlarged view showing part D of FIG. 9;

FIG. 11 is a cross-sectional view taken along the line E-E′ of FIG. 10 according to some embodiments;

FIG. 12 is a schematic diagram showing part C of FIG. 5 according to some embodiments;

FIGS. 13, 14, 15 and 16 are cross-sectional views taken along the line F-F′ of FIG. 12 according to some embodiments;

FIG. 17 is a block diagram of an electronic device according to some embodiments; and

FIG. 18 is schematic views of electronic devices according to some embodiments.

### DETAILED DESCRIPTION

Aspects of some embodiments according to the present disclosure will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

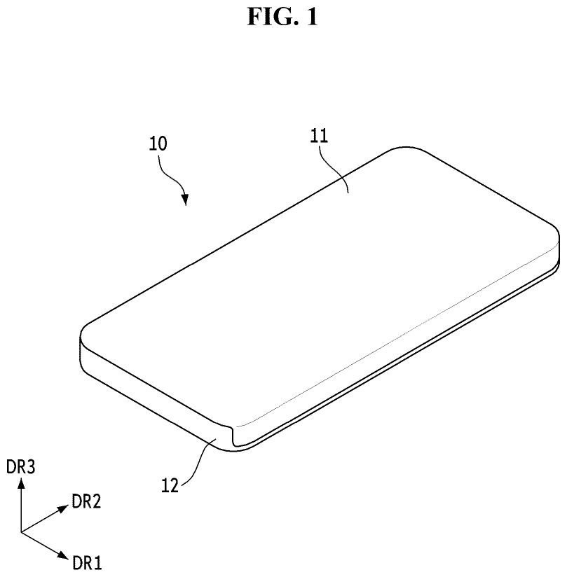

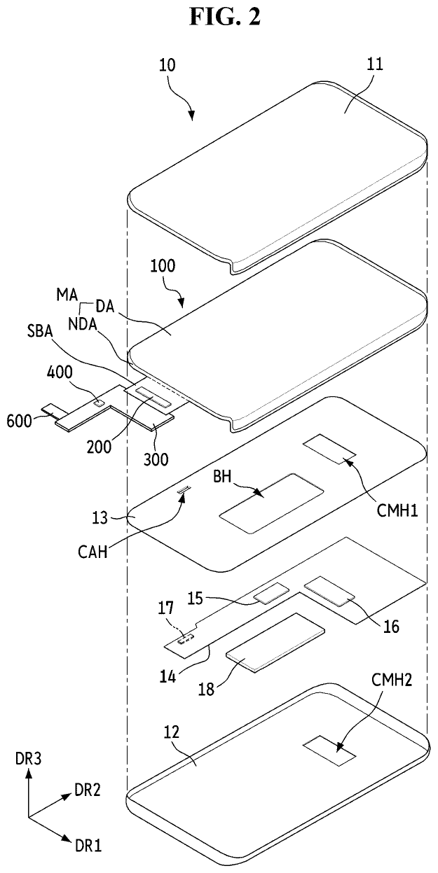

FIG. 1 is a perspective view showing an electronic device according to some embodiments. FIG. 2 is an exploded perspective view of the electronic device shown in FIG. 1.

Referring to FIG. 1, an electronic device 10 according to some embodiments is a device having a function of displaying an image in a display area. The electronic device 10 may provide portability. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to some embodiments is not limited to a portable electronic device, and may be a large-sized device such as a television, a laptop computer, a monitor, a billboard, and an Internet-of-Things (IoT) device.

The electronic device 10 according to some embodiments may include a cover window 11 and a lower cover 12, which are provided as a housing to protect a display device 100 (see FIG. 2).

Referring to FIG. 2, the electronic device 10 may further include the display device 100, a bracket 13, and a main circuit board 14, which are accommodated between the cover window 11 and the lower cover 12.

The display device 100 may include a main region MA including a display area DA where an image is displayed and a non-display area NDA around (e.g., in a periphery or outside a footprint of) the display area DA, and a sub-region SBA protruding from one side of the main region MA.

The display device 100 may further include a display driving circuit 200 located in the sub-region SBA, a display circuit board 300 bonded to one side of the sub-region SBA, a touch driving circuit 400 mounted on the display circuit board 300, and a cable 600 extending from one side of the display circuit board 300.

In the present specification, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 may have a shape close to a rectangular shape in a plan view (e.g., a view toward the display surface or along the third direction DR3). For example, the electronic device 10 may have a rectangular shape, in a plan view, having a short side in the first direction DR1 and a long side in the second direction DR2. A corner where the short side in the first direction DR1 and the long side in the second direction DR2 meet may be right-angled or rounded with a selected curvature. The planar shape of the electronic device 10 is not limited to the rectangular shape, and may be formed in another polygonal shape, a circular shape, an elliptical shape, or an irregular shape.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

That is, the cover window 11 may be located on the display device 100.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

The display device 100 may include the main region MA serving as a display surface and the sub-region SBA protruding from at least a part of one side of the main region MA.

The main region MA may include the display area DA displaying an image and the non-display area NDA that is a peripheral area of the display area DA.

The display area DA may be located in most of the main region MA. The display area DA may be located at the center of the main region MA.

In other words, each of the top, left, and right surface portions of the display device 100 may include the display area DA and the non-display area NDA.

The display area DA may be located on most of each of the top, left, and right surface portions of the display device 100.

The non-display area NDA may be located outside the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto.

Because a part of the sub-region SBA is transformed to be bent, another part of the sub-region SBA may overlap the main region MA in the third direction DR3.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

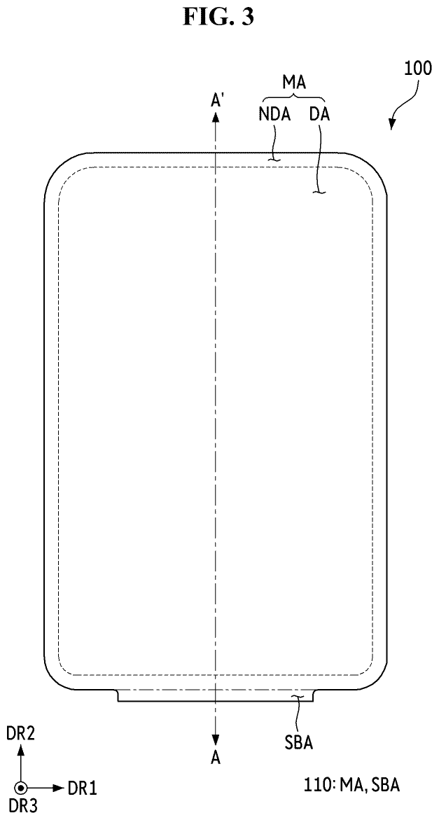

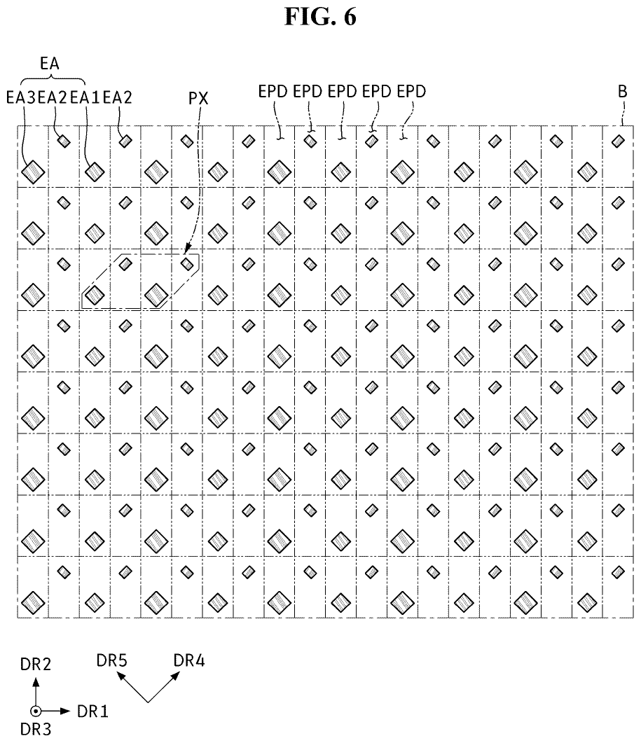

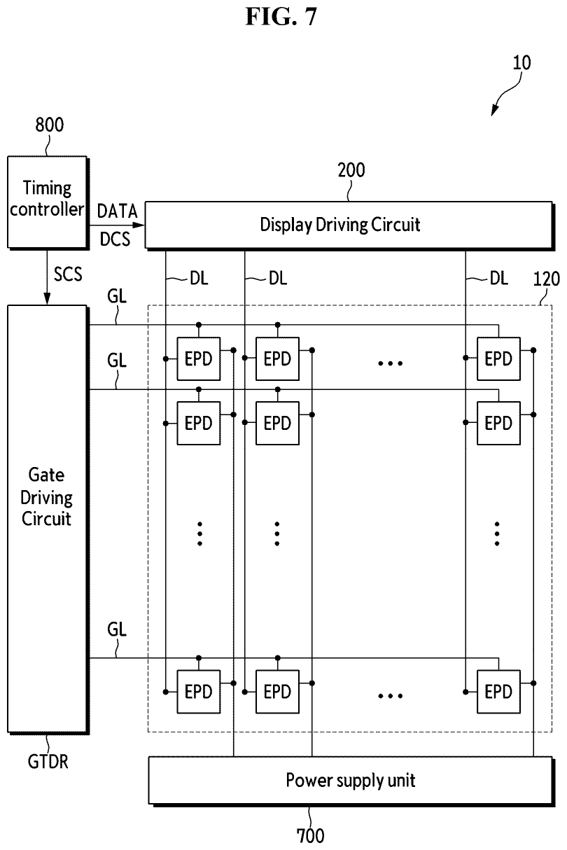

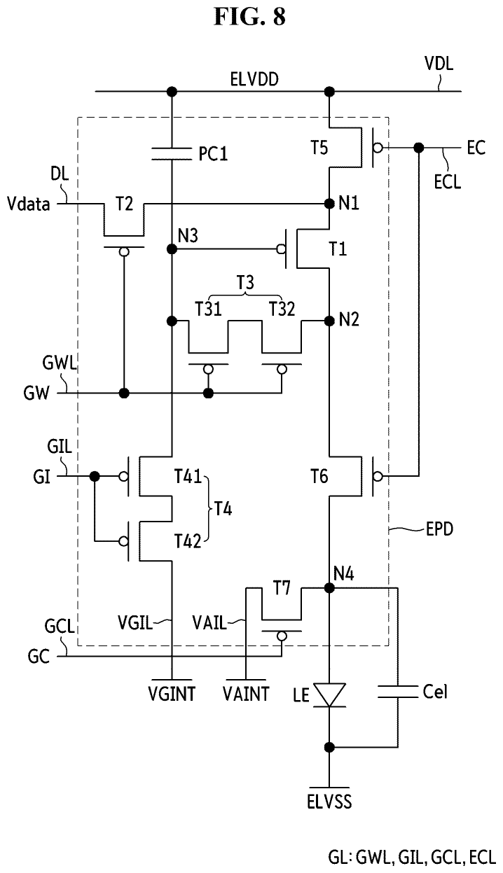

The display driving circuit 200 may output data signals Vdata (see FIG. 8) of data lines DL (see FIGS. 7 and 8) of a circuit layer 120 (see FIG. 3) located in the display area DA based on control signals, powers, and voltages supplied through the display circuit board 300. The data signals Vdata (see FIG. 8) may be transmitted to light emitting pixel drivers EPD (see FIGS. 6 and 7) through the data lines DL (see FIGS. 7 and 8).

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and embodiments according to the present disclosure are not limited thereto. For example, the display driving circuit 200 may be mounted on the display circuit board 300.

According to some embodiments, the touch driving circuit 400 may be further mounted on the sub-region SBA of the display device 100.

Alternatively, as shown in FIG. 2, the touch driving circuit 400 may be mounted on the display circuit board 300.

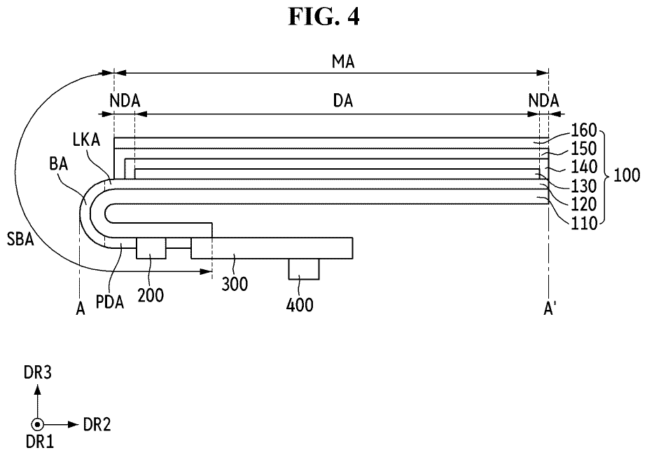

The touch driving circuit 400 may be electrically connected to a touch sensor layer 150 (see FIG. 4) of the display device 100.

As shown in FIG. 2, the bracket 13 may be located under the display device 100.

The bracket 13 may include plastic or metal. The bracket 13 may include a first camera hole CMH1 into which a camera device 16 is inserted, a battery hole BH into which a battery 18 is located, and a cable hole CAH through which the cable 600 connected to the display circuit board 300 passes.

The main circuit board 14 and the battery 18 may be located under the bracket 13.

The main circuit board 14 may be a printed circuit board or a flexible printed circuit board.

The main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or approached, and then perform an operation corresponding to the user's touch input or approach input. For example, the main processor 15 may perform an operation or execute an application indicated by an icon touched by the user.

The main processor 15 may be an application processor formed as an integrated circuit, a central processing unit, or a system chip.

The camera device 16 processes an image frame of a still image or video obtained by an image sensor in a camera mode and outputs it to the main processor 15.

The cable 600 having passed through the cable hole CAH of the bracket 13 may be connected to the main connector 17. Thus, the main circuit board 14 may be electrically connected to the display circuit board 300.

The battery 18 may be located so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18. The lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not limited by the illustration in FIG. 2.

Next, the display device 100 according to some embodiments will be described.

FIG. 3 is a plan view illustrating the display device of FIG. 2. FIG. 4 is a cross-sectional view taken along the line A-A′ of FIG. 3.

Referring to FIGS. 3 and 4, the display device 100 according to some embodiments, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 3, at least one surface of the display device 100 includes the main region MA from which light for displaying an image is emitted.

The display area DA may, in a plan view, be formed in a rectangular shape having short sides in the first direction DR1 and long sides in the second direction DR2 crossing the first direction DR1. The corner where the short side in the first direction DR1 and the long side in the second direction DR2 meet may be rounded to have a selected curvature or may be right-angled. The planar shape of the display area DA is not limited to the rectangular shape, and may be formed in another polygonal shape, a circular shape or an elliptical shape.

The display area DA may be located in most of the main region MA. The display area DA may be located at the center of the main region MA.

Referring to FIG. 4, the display device 100 may further include the sub-region SBA protruding from a part of an edge of the main region MA.

For example, the sub-region SBA may protrude from a part of one side of the main region MA in the second direction DR2.

The sub-region SBA may include a bending area BA, which is transformed into a bent shape, and a pad area PDA, which is connected to one side of the bending area BA.

When the bending area BA is transformed into a bent shape, the pad area PDA may be located on the rear surface of the display device 100 and may overlap the main region MA in the third direction DR3.

The sub-region SBA may further include a link area LKA located between the other side of the bending area BA and the main region MA.

According to some embodiments, the display device 100 may include the substrate 110 and the circuit layer 120 located on the substrate 110.

The display device 100 may further include an element layer 130 located on the circuit layer 120, an encapsulation layer 140 located on the element layer 130, and a touch sensor layer 150 located on the encapsulation layer 140.

The display device 100 may further include a polarization layer 160 located on the touch sensor layer 150, in order to reduce reflection of external light.

The substrate 110 may include the main region MA corresponding to the display surface, and the sub-region SBA protruding in the second direction DR2 from at least a part of one side of the main region MA.

The main region MA of the substrate 110 may include the display area DA from which light is emitted, and the non-display area NDA located around the display area DA.

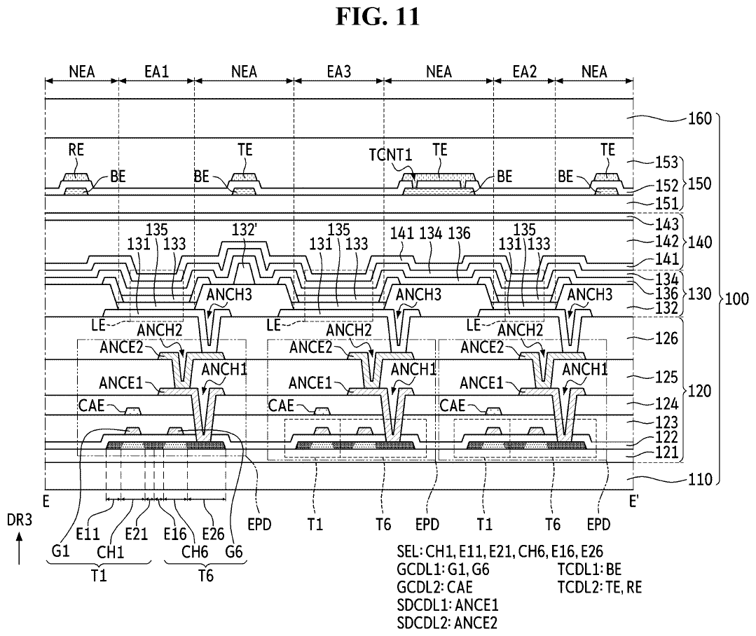

According to some embodiments, the element layer 130 may include light emitting elements LE (see FIGS. 8 and 11) respectively located in the emission areas EA (see FIG. 6).

The circuit layer 120 may include the light emitting pixel drivers EPD (see FIGS. 6, 7, and 8) electrically connected to the light emitting elements LE, and the data lines DL (see FIGS. 7 and 8) that transmit the data signal Vdata (see FIG. 8) of the light emitting pixel drivers EPD.

The encapsulation layer 140 may cover the element layer 130. The encapsulation layer 140 may include a structure in which two or more inorganic films and at least one organic film are alternately stacked.

The touch sensor layer 150 may be located on the encapsulation layer 140 and may correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and this is to prevent or reduce the deterioration of visibility of images due to external light reflection.

The display driving circuit 200 may be mounted on the pad area PDA of the sub-region SBA of the substrate 110.

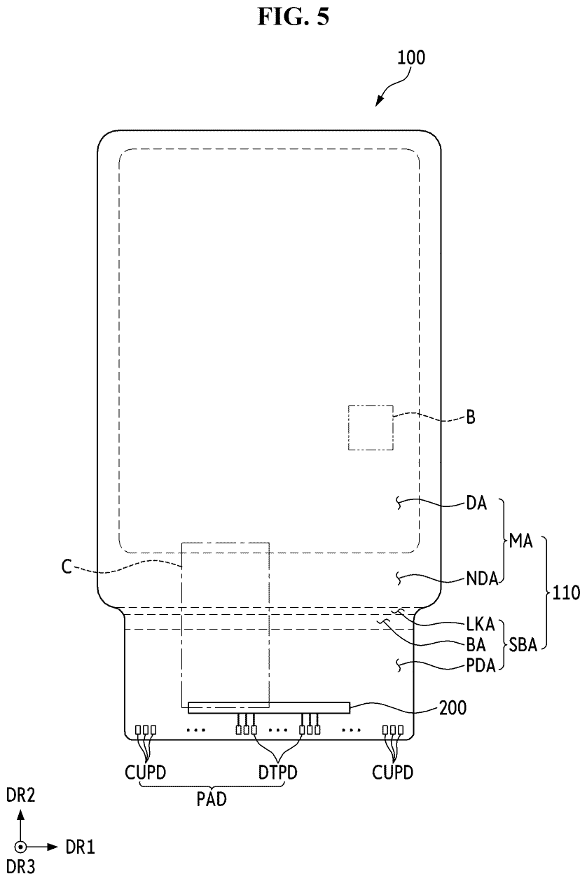

The display circuit board 300 may be connected to pads PAD (see FIG. 5) arranged in the pad area PDA in the sub-region SBA of the substrate 110.

When the bending area BA is transformed into a bent shape, the display driving circuit 200 and the display circuit board 300 may be placed under the substrate 110.

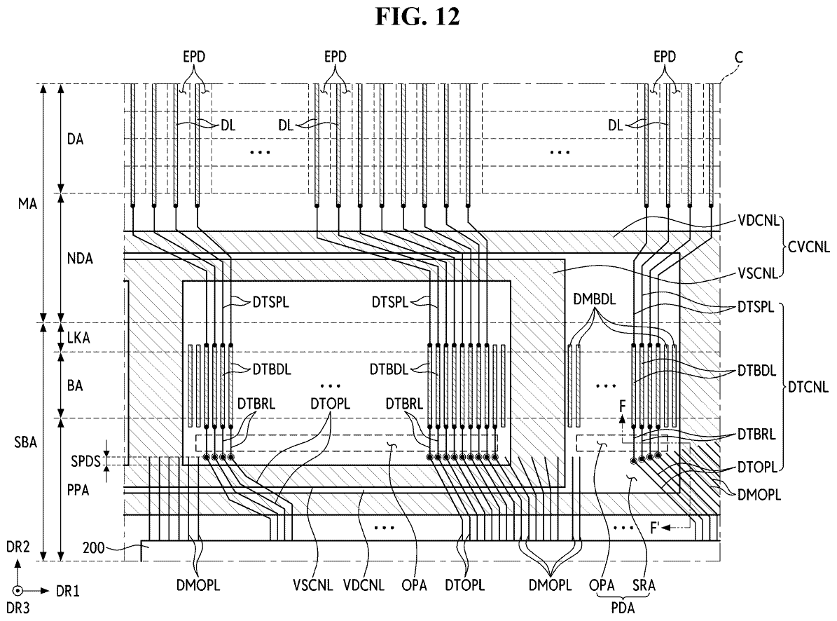

The display driving circuit 200 may be electrically connected to the data lines DL (see FIGS. 7 and 8) through data connection lines DTCNL (see FIG. 12). The display driving circuit 200 may output the data signals Vdata (see FIG. 8) of the light emitting pixel drivers EPD (see FIGS. 6, 7, and 8) to the data lines DL based on control signals and power voltages supplied from the display circuit board 300.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and embodiments according to the present disclosure are not limited thereto. For example, the display driving circuit 200 may be mounted on the display circuit board 300.

One end of the display circuit board 300 may be attached and connected to the pads PAD (see FIG. 5) using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

The touch driving circuit 400 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user has touched or approached.

The user's touch means that an object such as a pen or a user's finger is in direct contact with the top surface of the cover window located on the touch sensor layer. The user's approach means that the object such as the pen or the user's finger hovers over the top surface of the cover window.

The touch driving circuit 400 may output touch data including the user's touch coordinates to the main processor 15 (see FIG. 2).

FIG. 5 is a plan view illustrating the substrate of FIG. 4 according to some embodiments.

Referring to FIG. 5, the substrate 110 of the display device 100 according to some embodiments may include the main region MA corresponding to the display surface, and the sub-region SBA protruding from a part of an edge of the main region MA.

The main region MA may include the display area DA located at most of the center of the main region MA, and the non-display area NDA located around the display area DA.

The sub-region SBA may include the bending area BA, which is transformed into a bent shape, and the pad area PDA, which is connected to one side of the bending area BA.

The display driving circuit 200 may be mounted on the pad area PDA.

The display device 100 according to some embodiments may include the pads PAD arranged on one side of the pad area PDA.

The display circuit board 300 may be attached and connected to the pads PAD.

The pads PAD may include data pads DTPD electrically connected to the display driving circuit 200 and constant voltage transfer pads CVPD transmitting a constant voltage.

According to some embodiments, the constant voltage may include a first power ELVDD (see FIG. 8) and a second power ELVSS (see FIG. 8) for generating a driving current of the light emitting elements LE (see FIGS. 8 and 11), a gate initialization voltage VGINT for initializing the light emitting pixel driver EPD (see FIGS. 7 and 8), and an anode initialization voltage VAINT for initializing the light emitting element LE.

FIG. 6 is a schematic diagram showing part B of FIG. 5.

As shown in FIG. 6, the emission areas EA may be arranged in the display area DA (see FIG. 5).

The display area DA may include a non-emission area located between the emission areas EA.

The element layer 130 (see FIG. 4) may include light emitting elements LE (see FIGS. 8 and 11) respectively located in the emission areas EA.

The circuit layer 120 (see FIG. 4) may include the light emitting pixel drivers EPD electrically connected to the light emitting elements LE.

The light emitting pixel drivers EPD may be arranged side by side in the first direction DR1 and the second direction DR2 in the display area DA.

The emission areas EA may have a rhombic shape or a rectangular shape in a plan view. However, this is only an example, and the planar shape of the emission areas EA according to some embodiments is not limited to that illustrated in FIG. 5. That is, in a plan view, the emission areas EA may have a polygonal shape such as a quadrangle, a pentagon, and a hexagon, or may have a circular or elliptical shape including the edge of a curve.

The emission areas EA may include first emission areas EA1 emitting light of a first color in a selected wavelength band, second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately located in at least one of the first direction DR1 or the second direction DR2.

The second emission areas EA2 may be arranged side by side with each other in at least one of the first direction DR1 or the second direction DR2.

In addition, the second emission areas EA2 may be adjacent to the first emission areas EA1 and the third emission areas EA3 in diagonal directions DR4 and DR5 crossing the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixel PX may be a basic unit for displaying various colors including white with a selected luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 7 is a block diagram illustrating a display device according to some embodiments.

Referring to FIG. 7, the circuit layer 120 of the display device 100 according to some embodiments may include the light emitting pixel drivers EPD electrically connected to the light emitting elements LE (see FIGS. 8 and 11) arranged in the emission areas EA (see FIG. 6), and the data lines DL that transmit the data signals Vdata (see FIG. 8) to the light emitting pixel drivers EPD.

The circuit layer 120 may further include one or more gate lines GL that transmit one or more gate signals to the light emitting pixel drivers EPD.

According to some embodiments, the display device 100 may further include the display driving circuit 200 that outputs the data signals Vdata (see FIG. 8) corresponding to the luminance of each of the light emitting elements LE to the data lines DL.

According to some embodiments, the display device 100 may further include a gate driver GTDR that outputs gate signals to the gate lines GL, a power supply unit 700 that supplies power and voltages to the light emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driver GTDR.

The display driving circuit 200 may convert the image data DATA into analog data voltages and output them to the data lines DL.

The gate driver GTDR may generate gate signals in response to the scan control signal SCS and sequentially output the gate signals to gate lines GL.

The gate lines GL may include a scan write line GWL (see FIG. 8) that transmits a scan write signal GW (see FIG. 8), a scan initialization line GIL (see FIG. 8) that transmits a scan initialization signal GI (see FIG. 8), an emission control line ECL (see FIG. 8) that transmits an emission control signal EC (see FIG. 8), and a gate control line GCL (see FIG. 8) that transmits a gate control signal GC (see FIG. 8).

The gate signals may have pulses that vary to a first gate level voltage or a second gate level voltage.

The power supply unit 700 may supply various power and voltages necessary for driving the light emitting pixel drivers EPD.

For example, the power supply unit 700 may supply a constant voltage such as the first power ELVDD (see FIG. 8) and the second power ELVSS (see FIG. 8) for generating a driving signal transmitted to the light emitting elements LE (see FIGS. 8 and 11), the gate initialization voltage VGINT (see FIG. 8) for initializing the light emitting pixel drivers EPD, and the anode initialization voltage VAINT (see FIG. 8) for initializing the light emitting elements LE (see FIG. 8).

FIG. 8 is an equivalent circuit diagram showing the light emitting pixel driver of FIG. 7 according to some embodiments. Although FIG. 8 illustrates various components in a circuit diagram, embodiments according to the present disclosure are not limited thereto, and according to some embodiments, the circuit may include additional components, or fewer components, without departing from the spirit and scope of embodiments according to the present disclosure.

Referring to FIG. 8, the circuit layer 120 (see FIG. 4) may include a first power line VDL for transmitting the first power ELVDD to the light emitting pixel drivers EPD, a second power line VSL for transmitting the second power ELVSS to the light emitting elements LE, a gate initialization voltage line VGIL for transmitting the gate initialization voltage VGINT to the light emitting pixel drivers EPD, and an anode initialization voltage line VAIL for transmitting the anode initialization voltage VAINT.

The circuit layer 120 (see FIG. 4) may further include the scan write line GWL for transmitting the scan write signal GW, the scan initialization line GIL for transmitting the scan initialization signal GI, the emission control line ECL for transmitting the emission control signal EC, and the gate control line GCL for transmitting the gate control signal GC.

The light emitting elements LE of the element layer 130 (see FIG. 4) may be electrically connected between the light emitting pixel drivers EPD and a second power source ELVSS.

That is, one of the light emitting elements LE may be electrically connected between one of the light emitting pixel drivers EPD of the circuit layer 120 and the second power source ELVSS.

The second power ELVSS may be at a voltage level lower than that of the first power ELVDD.

That is, the anode electrode of the light emitting element LE may be electrically connected to the light emitting pixel driver EPD, and the cathode electrode of the light emitting element LE may be electrically connected to the second power line VSL that transmits the second power ELVSS.

A capacitor Cel connected in parallel with the light emitting element LE refers to a parasitic capacitance between the anode electrode and the cathode electrode.

One of the light emitting pixel drivers EPD of the circuit layer 120 (see FIG. 3) may include a first transistor T1 configured to generate a driving current for driving the light emitting element LE, two or more transistors T2 to T7 electrically connected to the first transistor T1, and at least one pixel capacitor PC1.

The first transistor T1 may be electrically connected between a first node N1 and a second node N2 and may generate a driving current. The first node N1 is electrically connected to the first electrode (e.g., source electrode) of the first transistor T1. The second node N2 is electrically connected to the second electrode (e.g., drain electrode) of the first transistor T1.

The first node N1 may be electrically connected to the first power line VDL through the fifth transistor T5.

The second node N2 may be electrically connected to the anode electrode of the light emitting element LE through the sixth transistor T6.

The pixel capacitor PC1 may be electrically connected between the first power line VDL and a third node N3. The third node N3 is electrically connected to the gate electrode of the first transistor T1.

That is, the gate electrode of the first transistor T1 may be electrically connected to the first power line VDL through the pixel capacitor PC1.

Accordingly, the potential of the gate electrode of the first transistor T1 may be maintained at the voltage charged in the pixel capacitor PC1.

The second transistor T2 may be electrically connected between the data line DL and the first node N1.

The second transistor T2 may be electrically connected between the first electrode of the first transistor T1 and the data line DL.

That is, the first electrode of the first transistor T1 may be electrically connected to the data line DL through the second transistor T2.

The second transistor T2 may be turned on by the scan write signal GW of the scan write line GWL.

The fifth transistor T5 may be electrically connected between the first node N1 and the first power line VDL.

The sixth transistor T6 may be electrically connected between the second node N2 and a fourth node N4. The fourth node N4 is electrically connected to the anode electrode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When the data signal Vdata of the data line DL is transmitted to the first electrode of the first transistor T1 through the turned-on second transistor T2, the voltage difference between the gate electrode of the first transistor T1 and the first electrode of the first transistor T1 may be a difference voltage between a first power source ELVDD and the data signal Vdata.

In this case, when the voltage difference between the gate electrode of the first transistor T1 and the first electrode of the first transistor T1, i.e., the gate-source voltage difference becomes equal to or greater than a threshold voltage, the first transistor T1 may be turned on, thereby generating a drain-source current of the first transistor T1 corresponding to the data signal Vdata.

Subsequently, when the fifth transistor T5 and the sixth transistor T6 are turned on, the first power source ELVDD, the first transistor T1, the light emitting element LE, and the second power source ELVSS may be connected in series. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

The first electrode of the first sub-transistor T31 may be connected to the gate electrode of the first transistor T1, the second electrode of the first sub-transistor T31 may be connected to the first electrode of the second sub-transistor T32, and the second electrode of the second sub-transistor T32 may be connected to the second electrode of the first transistor T1.

In this way, it may be possible to prevent or reduce the potential of the gate electrode of the first transistor T1 changing due to the leakage current caused by the third transistor T3 that is not turned on.

The first sub-transistor T31 and the second sub-transistor T32 may be turned on by the scan write signal GW of the scan write line GWL.

When the first sub-transistor T31 and the second sub-transistor T32 are turned on, the voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may include a plurality of sub-transistors connected in series. For example, the fourth transistor T4 may include a third sub-transistor T41 and a fourth sub-transistor T42.

The first electrode of the third sub-transistor T41 may be connected to the gate electrode of the first transistor T1, the second electrode of the third sub-transistor T41 may be connected to the first electrode of the fourth sub-transistor T42, and the second electrode of the fourth sub-transistor T42 may be connected to the gate initialization voltage line VGIL.

In this way, it may be possible to prevent or reduce the potential of the gate electrode of the first transistor T1 changing due to the leakage current caused by the fourth transistor T4 that is not turned on.

The third sub-transistor T41 and the fourth sub-transistor T42 may be turned on by the scan initialization signal GI of the scan initialization line GIL.

When the third sub-transistor T41 and the fourth sub-transistor T42 are turned on, the potential of the third node N3 may be initialized to the gate initialization voltage VGINT.

The seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL.

The seventh transistor T7 may be turned on by the gate control signal GC of the gate control line GCL.

Through the turned-on seventh transistor T7, the potential of the fourth node N4 may be initialized to the anode initialization voltage VAINT.

As shown in FIG. 6, according to some embodiments, the first to seventh transistors T1 to T7 may be formed as P-type MOSFETs. However, this is merely an example, and at least some of the first to seventh transistors T1 to T7 may be formed as N-type MOSFETs. For example, the third transistor T3 and the fourth transistor T4 may be provided as N-type MOSFETs.

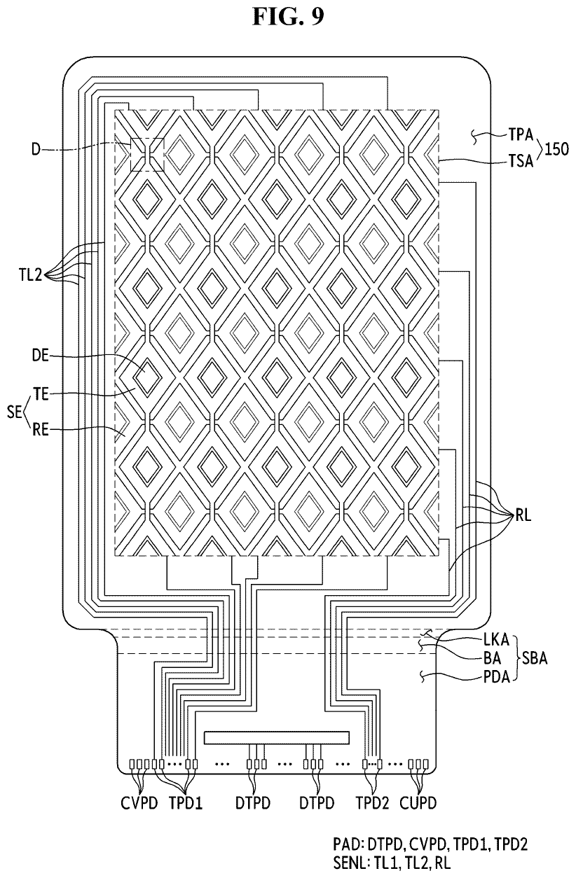

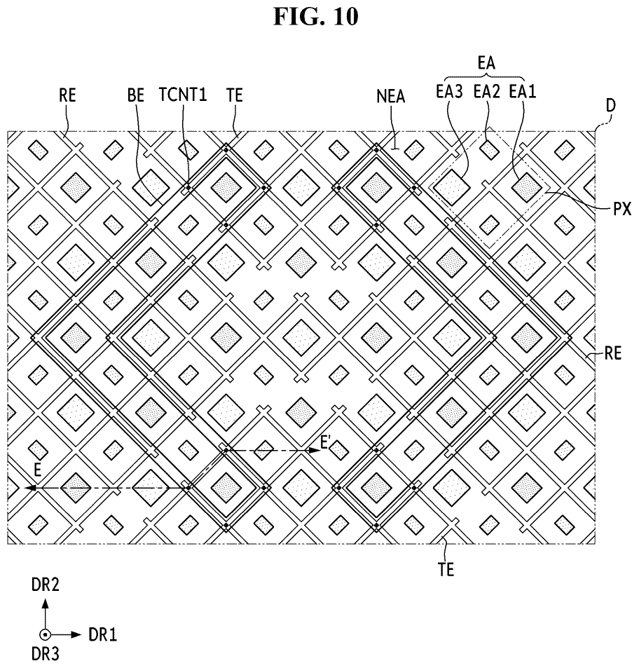

FIG. 9 is a plan view illustrating the touch sensor layer of FIG. 4 according to some embodiments. FIG. 10 is an enlarged view showing part D of FIG. 9. FIG. 11 is a cross-sectional view taken along the line E-E′ of FIG. 10 according to some embodiments.

FIG. 9 illustrates the touch sensor layer 150 of a capacitance method. In this case, the touch driving circuit 400 (see FIG. 4) may sense a touch based on whether capacitance fluctuations. However, the illustration in FIG. 9 is only an example for easy description, and the touch sensor layer 150 according to some embodiments is not limited to the illustration in FIG. 9.

FIG. 9 illustrates only some of the components of the touch sensor layer 150 for simplicity of description.

Referring to FIG. 9, the touch sensor layer 150 may be located in the main region MA. The touch sensor layer 150 may include a touch sensing area TSA for sensing a user's touch and a touch peripheral area TPA around the touch sensing area TSA.

The touch sensing area TSA has a wider width than the display area DA and may be similar to the display area DA. Accordingly, the touch peripheral area TPA, which is a periphery of the touch sensing area TSA, may be similar to the non-display area NDA, which is a periphery of the display area DA.

For example, the touch sensing area TSA may overlap the display area DA and the edge of the non-display area NDA in contact with the display area DA. In this case, the touch peripheral area TPA may overlap the remaining part of the non-display area NDA that does not correspond to the touch sensing area TSA.

The touch sensor layer 150 may include sensor electrodes SE and dummy electrodes DE that are matrix-arranged in the touch sensing area TSA and generate mutual capacitance, and sensing transmission lines SENL located in the touch peripheral area TPA.

The sensor electrodes SE may include a driving electrode TE (touch driving electrode) to which a driving signal is applied, and a sensing electrode RE (receiving electrode) to sense a voltage charged in mutual capacitance with the driving electrode TE.

The sensing transmission lines SENL may include a first driving line TL1, a second driving line TL2, and a sensing line RL.

Each of the first driving line TL1 and the second driving line TL2 may be electrically connected to two or more driving electrodes TE extending in the second direction DR2 among the driving electrodes TE.

The first driving line TL1 may extend from one side of the first direction DR1 that is adjacent to the sub-region SBA among the edges of the touch sensing area TSA to reach the sub-region SBA.

The second driving line TL2 may extend side by side with one side of the second direction DR2 from another side of the first direction DR1 that is spaced further apart from the sub-region SBA among the edges of the touch sensing area TSA to reach the sub-region SBA.

The sensing line RL may be electrically connected to two or more sensing electrodes RE extending in the first direction DR1 among the sensing electrodes RE.

The sensing electrodes RE may be arranged side by side in the first direction DR1. The sensing electrodes RE adjacent in the first direction DR1 may be electrically connected to each other through a protruding portion in the first direction DR1.

The driving electrodes TE may be arranged side by side in the second direction DR2. The driving electrodes TE adjacent in the second direction DR2 may be electrically connected to each other through a bridge electrode BE (see FIGS. 10 and 11) extending in the second direction DR2.

Each of the driving electrodes TE and the sensing electrodes RE may have a shape surrounding the dummy electrode DE located in the center thereof.

Each of the dummy electrodes DE may be spaced apart from the driving electrode TE or the sensing electrode RE that surrounds it. The dummy electrode DE may be maintained in a floating state.

FIG. 9 shows a case where each of the driving electrode TE, the sensing electrode RE, and the dummy electrode DE has a rhombus planar shape, but this is only an example. That is, the planar shape of the driving electrode TE, the sensing electrode RE, and the dummy electrode DE may be a quadrilateral shape other than a rhombus, a polygonal shape other than a quadrilateral shape, a circular shape, or an elliptical shape.

The display device 100 according to some embodiments may include the pads PAD that are located in the pad area PDA of the substrate 110 and to which the circuit board 300 (see FIGS. 2 and 4) is connected.

The pads PAD may include display pads DTPD electrically connected to the display driving circuit 200 or the wires of the circuit layer 120 (see FIG. 4), touch pads TPD1 and TPD2 electrically connected to the sensing transmission lines SENL of the touch sensor layer 150, and the constant voltage transfer pads CVPD that transmit a constant voltage.

The first driving line TL1 and the second driving line TL2 may be electrically connected to the first touch pads TPD1.

The sensing line RL may be electrically connected to the second touch pad TPD2.

Referring to FIG. 10, the touch sensor layer 150 may further include the bridge electrode BE that electrically connects the driving electrodes TE adjacent in the second direction DR2.

The bridge electrode BE may be electrically connected to the driving electrodes TE through touch electrode connection holes TCNT1.

The driving electrodes TE adjacent in the second direction DR2 may be electrically connected to each other through two or more bridge electrodes BE. In this way, reliability of the electrical connection between the driving electrodes TE may be relatively improved.

Although FIG. 10 illustrates that two bridge electrodes BE parallel to each other are located between the driving electrodes TE adjacent to each other in the second direction DR2, this is only an example.

Although FIG. 10 illustrates the bridge electrode BE having a shape including one bend, this is only an example.

The driving electrode TE and the sensing electrode RE may be spaced apart from each other.

The bridge electrode BE may be located in a different conductive layer from the driving electrode TE and the sensing electrode RE.

The driving electrode TE, the sensing electrode RE, and the bridge electrode BE may have a mesh or net structure in a plan view. The dummy electrodes DE may also have a mesh or net structure in a plan view. In this way, because the overlapping width of the driving electrode TE, the sensing electrode RE, the dummy electrode DE, and the bridge electrode BE in the emission areas EA may be reduced, a decrease in light emission efficiency of the emission areas EA due to the driving electrode TE, the sensing electrode RE, the dummy electrode DE, and the bridge electrode BE may be reduced.

Referring to FIG. 11, the display device 100 according to some embodiments may include the substrate 110, the circuit layer 120 on the substrate 110, the element layer 130 on the circuit layer 120, the encapsulation layer 140 on the element layer 130, and the touch sensor layer 150 on the encapsulation layer 140.

In addition, the display device 100 according to embodiments may further include the polarization layer 160 located on the touch sensor layer 150.

The circuit layer 120 may include a semiconductor layer SEL located on the substrate 110, a first gate insulating layer 122 covering the semiconductor layer SEL, a first gate conductive layer GCDL1 located on the first gate insulating layer 122, a second gate insulating layer 123 covering the first gate conductive layer GCDL1, a second gate conductive layer GCDL2 located on the second gate insulating layer 123, an interlayer insulating layer 124 covering the second gate conductive layer GCDL2, a first source-drain conductive layer SDCDL1 located on the interlayer insulating layer 124, a first planarization layer 125 covering the first source-drain conductive layer SDCDL1, a second source-drain conductive layer SDCDL2 located on the first planarization layer 125, and a second planarization layer 126 covering the second source-drain conductive layer SDCDL2.

The circuit layer 120 may further include the buffer layer 121 covering the substrate 110.

In this case, the semiconductor layer SEL may be located on the buffer layer 121.

The circuit layer 120 may include the light emitting pixel drivers EPD respectively corresponding to the emission areas EA.

Each of the light-emitting pixel drivers EPD may include the first transistor T1, the second to seventh transistors T2 to T7 (see FIG. 8) electrically connected to the first transistor T1, and at least one pixel capacitor PC1 (see FIG. 8).

FIG. 11 shows the first transistor T1, the sixth transistor T6, and the light emitting element LE of FIG. 8 according to some embodiments.

Channel portions CH1 and CH6, first electrode portions E11 and E16, and second electrode portions E21 and E26 of the respective first and sixth transistors T1 and T6 formed as P-type MOSFETs may be located in the semiconductor layer SEL.

In the first transistor T1 and the sixth transistor T6, the first electrode portions E11 and E16 may be connected to one ends of the channel portions CH1 and CH6, and the second electrode portions E21 and E26 may be connected to the other ends of the channel portions CH1 and CH6.

The second electrode portion E21 of the first transistor T1 may be connected to the first electrode portion E16 of the sixth transistor T6.

Gate electrodes G1 and G6 of the respective first transistor T1 and sixth transistor T6 formed as P-type MOSFETs may be located in the first gate conductive layer GCDL1.

In the first transistor T1 and the sixth transistor T6, the gate electrodes G1 and G6 may overlap the channel portions CH1 and CH6, respectively.

In the light emitting pixel driver EPD of FIG. 8, the second transistor T2, the first sub-transistor T31, the second sub-transistor T32, the third sub-transistor T41, the fourth sub-transistor T42, the fifth transistor T5, and the seventh transistor T7 are formed as the same P-type MOSFET as the first and sixth transistors T1 and T6, and therefore some redundant description thereof may be omitted below.

The second gate conductive layer GCDL2 may include a capacitor electrode CAE.

The capacitor electrode CAE may overlap the gate electrode G1 of the first transistor T1.

The capacitor electrode CAE may be electrically connected to the first power line VDL (see FIG. 8).

Accordingly, the pixel capacitor PC1 (see FIG. 8) may be provided by a region in which the capacitor electrode CAE and the gate electrode G1 of the first transistor T1 overlap each other in the third direction DR3.

Each of the buffer layer 121, the first gate insulating layer 122, the second gate insulating layer 123, and the interlayer insulating layer 124 may include an inorganic insulating material.

The first source-drain conductive layer SDCDL1 on the interlayer insulating layer 124 may include the first anode connection electrode ANCE1.

The first anode connection electrode ANCE1 may be electrically connected to the second electrode portion E26 of the sixth transistor T6 through a first anode connection hole ANCH1.

The second source-drain conductive layer SDCDL2 on the first planarization layer 125 may include a second anode connection electrode ANCE2.

The second anode connection electrode ANCE2 may be electrically connected to the first anode connection electrode ANCE1 through the second anode connection hole ANCH2.

An anode electrode 131 of the element layer 130 may be located on the second planarization layer 126, and may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

The element layer 130 on the circuit layer 120 may include the light emitting elements LE respectively located in the emission areas EA1, EA2, and EA3.

Each of the light emitting elements LE may include a structure in which a light emitting layer 133 is located between the anode electrode 131 and a cathode electrode 134 facing each other.

In accordance with embodiments, the element layer 130 may include the anode electrodes 131 respectively located in the emission areas EA, a pixel defining layer 132 located in the non-emission area NEA and covering the edge of the anode electrode 131, a spacer layer 132′ located on a part of the pixel defining layer 132, the light emitting layers 133 respectively located on the anode electrodes 131, and the cathode electrode 134 located on the light emitting layers 133, the pixel defining layer 132, and the spacer layer 132′.

Alternatively, each of the light emitting elements LE may further include first common layers 135 located between the anode electrodes 131 and the light emitting layers 133, and a second common layer 136 located between the light emitting layers 133 and the cathode electrode 134.

The encapsulation layer 140 may cover the element layer 130.

The encapsulation layer 140 is to block the permeation of oxygen or moisture into the element layer 130 and to reduce electrical or physical impact to the circuit layer 120 and the element layer 130.

The encapsulation layer 140 may include a first encapsulation layer 141 covering the element layer 130 and containing an inorganic insulating material, a second encapsulation layer 142 located on the first encapsulation layer 141 and containing an organic insulating material, and a third encapsulation layer 143 covering the second encapsulation layer 142 and containing an inorganic insulating material.

The touch sensor layer 150 may be located on the encapsulation layer 140.

The touch sensor layer 150 may include a touch buffer layer 151 located on the encapsulation layer 140, a first touch conductive layer TCDL1 located on the touch buffer layer 151, a touch interlayer insulating layer 152 covering the first touch conductive layer TCDL1, a second touch conductive layer TCDL2 located on the touch interlayer insulating layer 152, and a touch planarization layer 153 covering the second touch conductive layer TCDL2.

The first touch conductive layer TCDL1 on the touch buffer layer 151 may include the bridge electrode BE.

The second touch conductive layer TCDL2 on the touch interlayer insulating layer 152 may include the driving electrode TE and the sensing electrode RE.

The dummy electrode DE located inside each of the driving electrode TE and the sensing electrode RE, the first driving line TL1 and the second driving line TL2 connected to the driving electrode TE, and the sensing line RL connected to the sensing electrode RE may be located in the second touch conductive layer on the touch interlayer insulating layer 152, similarly to the driving electrode TE and the sensing electrode RE.

The driving electrode TE may be electrically connected to the bridge electrode BE through the touch electrode connection hole TCNT1 penetrating the touch interlayer insulating layer 152.

The touch buffer layer 151 may include an inorganic insulating material.

The touch interlayer insulating layer 152 may include an inorganic insulating material or an organic insulating material.

The touch planarization layer 153 may contain an organic insulating material.

The polarization layer 160 may be located on the touch sensor layer 150.

FIG. 12 is a schematic diagram showing part C of FIG. 5 according to some embodiments.

As shown in FIG. 4 described above, the display device 100 according to some embodiments may include the substrate 110, the circuit layer 120 located on the substrate 110, and the display driving circuit 200 that outputs the data signals Vdata (see FIG. 8) of the data lines DL of the circuit layer 120.

The substrate 110 may include the main region MA and the sub-region SBA protruding from a part of an edge of the main region MA.

The sub-region SBA may include the bending area BA that is adjacent to the main region MA and transformed into a bent shape, and the pad area PDA connected to one side of the bending area BA.

As illustrated in FIG. 12, according to some embodiments, the pad area PDA may include at least one open area OPA located adjacent to and parallel to the bending area BA and an open peripheral area SRA surrounding the at least one open area OPA.

The display driving circuit 200 may be located in the open peripheral area SRA.

The data lines DL may be electrically connected to the display driving circuit 200 through the data connection lines DTCNL.

According to some embodiments, each of the data connection lines DTCNL may include a data output line DTOPL electrically connected to the display driving circuit 200 and located in the open peripheral area SRA, a data bending line DTBDL located in the bending area BA, and a data bridge line DTBRL located in the at least one open area OPA and electrically connected between the data output line DTOPL and the data bending line DTBDL.

Thus, according to some embodiments, each of the data connection lines DTCNL includes the data bridge line DTBRL that overlaps the at least one open area OPA, separately from the data output line DTOPL, so that the data output line DTOPL does not overlap the at least one open area OPA.

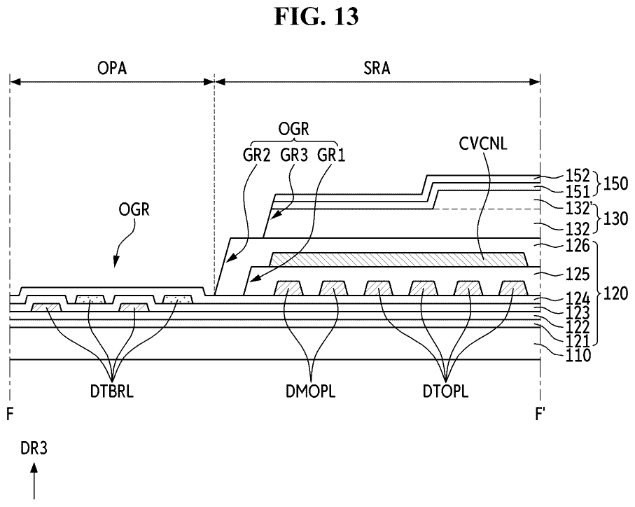

In this way, a defect, in which the data output line DTOPL is corroded due to at least one open groove OGR (see FIG. 13) formed in the at least one open area OPA, may be delayed, prevented, or reduced.

According to some embodiments, each of the data connection lines DTCNL may further include a data supply line DTSPL located in the non-display area NDA and electrically connected to the data bending line DTBDL.

The data supply lines DTSPL of the data connection lines DTCNL may be electrically connected to the data lines DL.

According to some embodiments, the display device 100 may further include constant voltage connection lines CVCNL arranged in the open peripheral area SRA, the bending area BA, and the non-display area NDA and transmitting a constant voltage.

The constant voltage connection lines CVCNL may include a first power connection line VDCNL transmitting the first power ELVDD (see FIG. 8) and a second power connection line VSCNL transmitting the second power ELVSS (see FIG. 8).

Some of the data output lines DTOPL of the data connection lines DTCNL may overlap the constant voltage connection lines CVCNL in the thickness direction of the substrate 110 (i.e., the third direction DR3).

In this way, poor coupling between signals transmitted through the data output lines DTOPL may be decreased by the constant voltage of the constant voltage connection lines CVCNL.

According to some embodiments, the display device 100 may further include dummy output lines DMOPL located in the open peripheral area SRA and arranged between the data output lines DTSPL.

The dummy output lines DMOPL may be spaced apart from the bending area BA and the at least one open area OPA.

The dummy output lines DMOPL may overlap the constant voltage connection lines CVCNL in the thickness direction of the substrate 110 (i.e., the third direction DR3).

According to some embodiments, the display device 100 may further include one or more dummy bending lines DMBDL located between the data bending lines DTBDL and the constant voltage connection lines CVCNL in the bending area BA.

According to some embodiments, in the open peripheral area SRA, a minimum separation distance SPDS between the data bridge line DTBRL and the constant voltage connection line CVCNL may be about 50 μm or greater.

FIGS. 13, 14, 15 and 16 are cross-sectional views taken along the line F-F′ of FIG. 12 according to some embodiments.

As illustrated in FIG. 13, the display device 100 according to some embodiments may further include at least one open groove OGR overlapping the at least one open area OPA.

The at least one open groove OGR may be formed in the first planarization layer 125 and the second planarization layer 126.

That is, the at least one open groove OGR may include a first groove GR1 formed in the first planarization layer 125 and a second groove GR2 formed in the second planarization layer 126.

In this way, according to some embodiments, the interlayer insulating layer 124 may be exposed through the at least one open groove OGR.

For example, the second groove GR2 may have a less width than that of the first groove GR1. Accordingly, at the edge of the open peripheral area SRA, the second planarization layer 126 may cover the edge of the first groove GR1 and the first planarization layer 125.

For example, when the pixel defining layer 132 extends to the sub-region SBA, the at least one open groove OGR may be further formed in the pixel defining layer 132.

That is, the at least one open groove OGR may further include a third groove GR3 formed in the pixel defining layer 132.

The second groove GR2 may have a less width than that of the third groove GR3. Accordingly, at the edge of the open peripheral area SRA, the pixel defining layer 132 may be located on the second planarization layer 126.

According to some embodiments, in the open peripheral area SRA, the pixel defining layer 132 or the spacer layer 132′ may be covered with the touch buffer layer 151 or the touch interlayer insulating layer 152.

According to some embodiments, the data output line DTOPL may be located in the first source-drain conductive layer SDCDL1 (see FIG. 11) on the interlayer insulating layer 124.

Similarly to the data output line DTOPL, the dummy output line DMOPL may also be located in the first source-drain conductive layer SDCDL1 (see FIG. 11) on the interlayer insulating layer 124.

According to some embodiments, the data bridge line DTBRL located in the at least one open area OPA may be located in the first gate conductive layer GCDL1 (see FIG. 11) on the first gate insulating layer 122 or the second gate conductive layer GCDL2 (see FIG. 11) on the second gate insulating layer 123.

That is, the data bridge line DTBRL may be covered with the second gate insulating layer 123 or the interlayer insulating layer 124.

Accordingly, even if the at least one open groove OGR exposing the interlayer insulating layer 124 is formed in the at least one open area OPA, the data bridge line DTBRL is covered with at least the interlayer insulating layer 124, so that a corrosion defect of the data bridge line DTBRL may be prevented or delayed.

In addition, because the data output line DTOPL, which is located in the first source-drain conductive layer SDCDL1 (see FIG. 11) on the interlayer insulating layer 124, is spaced apart from the at least one open area OPA and covered with the first planarization layer 125, the corrosion defect of the data output line DTOPL due to the at least one open groove OGR exposing the interlayer insulating layer 124 may be prevented, reduced, or delayed.

Hence, the lifespan and quality reliability of the display device 100 may be relatively improved.

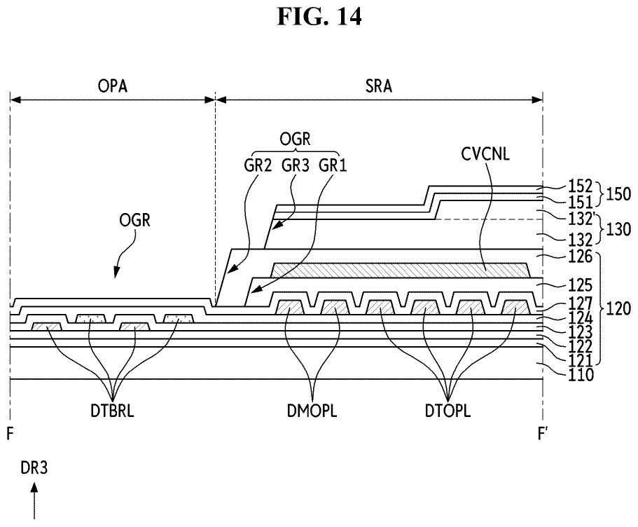

The display device 100 according to some embodiments as illustrated in FIG. 14 is substantially the same as or similar to the display device 100 according to some embodiments as illustrated in FIG. 13, except that the circuit layer 120 further includes a passivation layer 127 covering the interlayer insulating layer 124 and the data output line DTOPL, so that some redundant description may be omitted below.

According to some embodiments as illustrated in FIG. 14, the first planarization layer 125 may be located on the passivation layer 127.

The passivation layer 127 may include an inorganic insulating material.

In the at least one open area OPA, the passivation layer 127 may be exposed through the at least one open groove OGR.

Because the passivation layer 127 covers the interlayer insulating layer 124, the data bridge line DTBRL, which is located in the first gate conductive layer GCDL1 (see FIG. 11) on the first gate insulating layer 122 or the second gate conductive layer GCDL2 (see FIG. 11) on the second gate insulating layer 123, may be covered with the passivation layer 127 and at least one of the second gate insulating layer 123 or the interlayer insulating layer 124.

Accordingly, the corrosion defect of the data bridge line DTBRL may be further prevented, reduced, or delayed, so that the lifespan and quality reliability of the display device 100 may be further relatively improved.

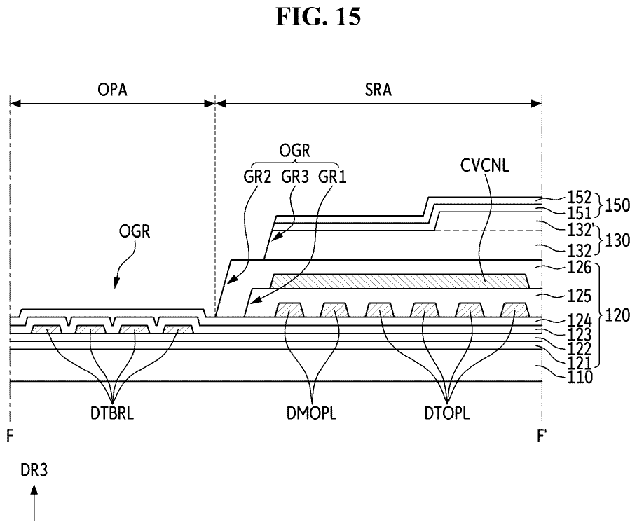

The display device 100 according to some embodiments as illustrated in FIG. 15 is substantially the same as or similar to the display device 100 according to some embodiments as illustrated in FIG. 13, except that the data bridge line DTBRL is not located in the first gate conductive layer GCDL1 (see FIG. 11) on the first gate insulating layer 122 or the second gate conductive layer GCDL2 (see FIG. 11) on the second gate insulating layer 123, but is located only in the first gate conductive layer GCDL1 (see FIG. 11) on the first gate insulating layer 122. Therefore, some redundant description thereof may be omitted below.

In this way, because the data bridge line DTBRL is covered with the second gate insulating layer 123 and the interlayer insulating layer 124, the corrosion defect of the data bridge line DTBRL may be further prevented, reduced, or delayed. Thus, the lifespan and quality reliability of the display device 100 may be further relatively improved.

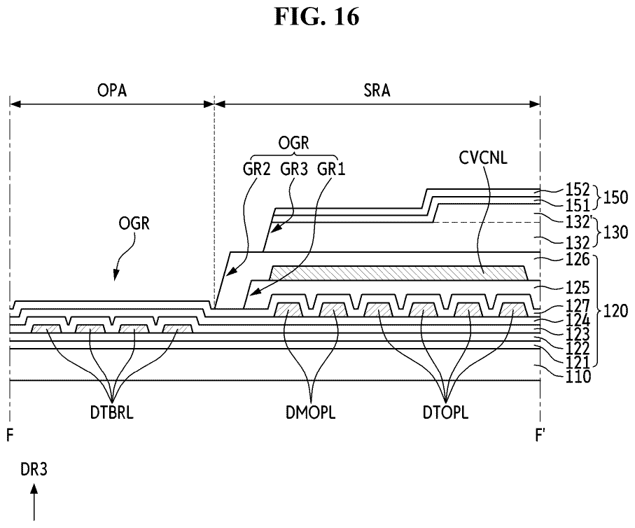

The display device 100 according to some embodiments as illustrated in FIG. 16 is substantially the same as or similar to the display device 100 according to some embodiments as illustrated in FIG. 15, except that the circuit layer 120 further includes the passivation layer 127 covering the interlayer insulating layer 124 and the data output line DTOPL. Therefore, some redundant description may be omitted below.

In this way, because the data bridge line DTBRL is covered with the second gate insulating layer 123, the interlayer insulating layer 124, and the passivation layer 127, the corrosion defect of the data bridge line DTBRL may be further prevented, reduced, or delayed. Accordingly, the lifespan and quality reliability of the display device 100 may be further relatively improved.

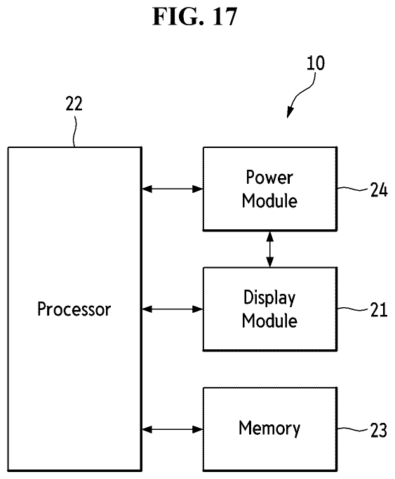

The display device 100 according to some embodiments as described above may be applied to various electronic devices 10 (see FIG. 17).

The electronic device 10 according to some embodiments may include the display device 100 described above.

Additionally, the electronic device 10 according to some embodiments may further include a module or device having other additional functions in addition to the display device 100.

FIG. 17 is a block diagram of an electronic device according to some embodiments.

Referring to FIG. 17, the electronic device 10 according to some embodiments may include a display module 21, a processor 22, a memory 23, and a power module 24.

The display module 21 may include the display device 100 for displaying an image.

The processor 22 may include at least one of a central processing unit (CPU), an application processor (AP), a graphic processing unit (GPU), a communication processor (CP), an image signal processor (ISP), or a controller.

The memory 23 may store data information required for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device 100 may include the display module 21, and the processor 22, the memory 23, and the power module 24 may be provided in the form of other devices in the electronic device 10 other than the display device 100.

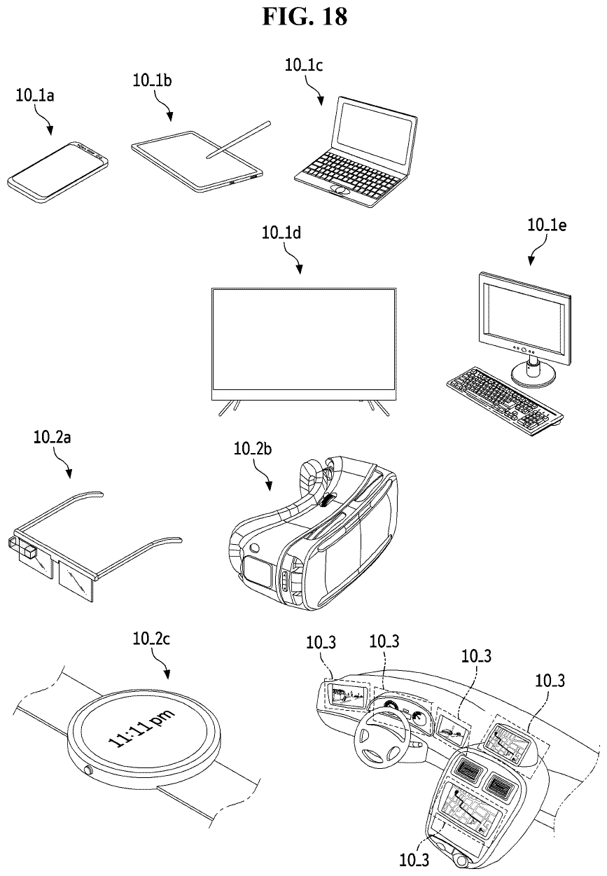

FIG. 18 is schematic views of electronic devices according to various embodiments.

Referring to FIG. 18, the electronic devices 10 according to the embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display.

However, the effects of the present disclosure are not restricted to the one set forth herein. The above and other effects of the present disclosure will become more apparent to one of daily skill in the art to which the present disclosure pertains by referencing the appended claims, and their equivalents.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the disclosed embodiments of the present invention.

What is claimed is:

1. A display device comprising:
a substrate;
a circuit layer on the substrate; and
a display driving circuit configured to output data signals of data lines of the circuit layer,
wherein the substrate comprises a main region, and a sub-region protruding from a part of an edge of the main region,
the sub-region comprises a bending area adjacent to the main region and transformed into a bent shape, and a pad area connected to one side of the bending area,
the pad area comprises at least one open area located adjacent to and parallel to the bending area, and an open peripheral area surrounding the at least one open area,
the display driving circuit is located in the open peripheral area, and
the data lines are electrically connected to the display driving circuit through data connection lines,
wherein each of the data connection lines comprises:
a data output line electrically connected to the display driving circuit and located in the open peripheral area;
a data bending line in the bending area; and
a data bridge line in the at least one open area and electrically connected between the data output line and the data bending line.

2. The display device of claim 1, wherein the circuit layer comprises:
a first gate insulating layer on the substrate;
a first gate conductive layer on the first gate insulating layer;
a second gate insulating layer covering the first gate conductive layer;
a second gate conductive layer on the second gate insulating layer;
an interlayer insulating layer covering the second gate conductive layer; and
a first source-drain conductive layer on the interlayer insulating layer,
wherein the data output line of each of the data connection lines is in the first source-drain conductive layer, and
the data bridge line of each of the data connection lines is in the first gate conductive layer or the second gate conductive layer.

3. The display device of claim 2, wherein the circuit layer further comprises:
a first planarization layer covering the first source-drain conductive layer;
a second source-drain conductive layer on the first planarization layer;
a second planarization layer covering the second source-drain conductive layer; and
at least one open groove overlapping the at least one open area and formed in the first planarization layer and the second planarization layer.

4. The display device of claim 3, wherein each of the second gate insulating layer and the interlayer insulating layer contains an inorganic insulating material,
the interlayer insulating layer is exposed through the at least one open groove, and
the data bridge line of each of the data connection lines is covered with the second gate insulating layer or the interlayer insulating layer.

5. The display device of claim 4, wherein the data bridge line of each of the data connection lines is in the first gate conductive layer and covered with the second gate insulating layer and the interlayer insulating layer.

6. The display device of claim 3, wherein the circuit layer further comprises a passivation layer covering the interlayer insulating layer and the data output lines of the data connection lines,
the first planarization layer is on the passivation layer,
each of the second gate insulating layer, the interlayer insulating layer, and the passivation layer contains an inorganic insulating material,
the passivation layer is exposed through the at least one open groove, and
the data bridge line of each of the data connection lines is covered with the passivation layer and at least one of the second gate insulating layer or the interlayer insulating layer.

7. The display device of claim 3, wherein the main region comprises a display area in which emission areas are arranged, and a non-display area around the display area,
the data lines are in the display area,
each of the data connection lines further comprises a data supply line in the non-display area and electrically connected to the data bending line, and
the data supply lines of the data connection lines are electrically connected to the data lines.

8. The display device of claim 7, further comprising:
an element layer on the circuit layer;
an encapsulation layer covering the element layer; and
a touch sensor layer on the encapsulation layer,
wherein the element layer comprises:
first electrodes in the emission areas;
a pixel defining layer in a non-emission area between the emission areas and covering edges of the first electrodes;
light emitting layers on the first electrodes; and
a second electrode on the pixel defining layer and the light emitting layers, and
the touch sensor layer further comprises:
a touch buffer layer on the encapsulation layer;
a touch interlayer insulating layer covering a first touch conductive layer on the touch buffer layer; and
a touch planarization layer covering a second touch conductive layer on the touch interlayer insulating layer,
wherein the pixel defining layer extends to the sub-region, and
the at least one open groove is further formed in the pixel defining layer.

9. The display device of claim 7, further comprising constant voltage connection lines in the open peripheral area, the bending area and the non-display area and configured to transmit a constant voltage,
wherein some of the data output lines of the data connection lines overlap the constant voltage connection lines in a thickness direction of the substrate.

10. The display device of claim 9, further comprising dummy output lines in the open peripheral area and between the data output lines,
wherein the dummy output lines are in the first source-drain conductive layer and spaced apart from the bending area and the at least one open area and overlap the constant voltage connection lines in the thickness direction of the substrate.

11. The display device of claim 9, wherein the constant voltage connection lines comprise:
a first power connection line configured to transmit the first power; and
a second power connection line configured to transmit a second power lower than the first power.

12. An electronic device comprising:
a display device configured to display an image;
a processor;
a memory coupled to the processor, the memory storing instructions that, when executed by the processor, cause the processor to transmit an image data signal and an input control signal to the display device; and
a power module transmitting power to the display device,
wherein the display device comprises:
a substrate;
a circuit layer on the substrate; and
a display driving circuit configured to output data signals of data lines of the circuit layer,
wherein the substrate comprises a main region, and a sub-region protruding from a part of an edge of the main region,
the sub-region comprises a bending area adjacent to the main region and transformed into a bent shape, and a pad area connected to one side of the bending area,
the pad area comprises at least one open area adjacent to and parallel to the bending area, and an open peripheral area surrounding the at least one open area,
the display driving circuit is in the open peripheral area, and
the data lines are electrically connected to the display driving circuit through data connection lines,
wherein each of the data connection lines comprises:
a data output line electrically connected to the display driving circuit and located in the open peripheral area;
a data bending line in the bending area; and
a data bridge line in the at least one open area and electrically connected between the data output line and the data bending line.

13. The electronic device of claim 12, wherein the circuit layer comprises:
a first gate insulating layer on the substrate;
a first gate conductive layer on the first gate insulating layer;
a second gate insulating layer covering the first gate conductive layer;
a second gate conductive layer on the second gate insulating layer;
an interlayer insulating layer covering the second gate conductive layer;
a first source-drain conductive layer on the interlayer insulating layer,
a first planarization layer covering the first source-drain conductive layer;
a second source-drain conductive layer on the first planarization layer;
a second planarization layer covering the second source-drain conductive layer; and
at least one open groove overlapping the at least one open area and formed in the first planarization layer and the second planarization layer.

14. The electronic device of claim 13, wherein each of the second gate insulating layer and the interlayer insulating layer contains an inorganic insulating material,
the interlayer insulating layer is exposed through the at least one open groove,
the data output line of each of the data connection lines is in the first source-drain conductive layer, and
the data bridge line of each of the data connection lines is in the first gate conductive layer or the second gate conductive layer and covered with the second gate insulating layer or the interlayer insulating layer.

15. The electronic device of claim 13, wherein each of the second gate insulating layer and the interlayer insulating layer contains an inorganic insulating material,
the interlayer insulating layer is exposed through the at least one open groove,
the data output line of each of the data connection lines is in the first source-drain conductive layer, and
the data bridge line of each of the data connection lines is in the first gate conductive layer and covered with the second gate insulating layer or the interlayer insulating layer.

16. The electronic device of claim 13, wherein the circuit layer further comprises a passivation layer covering the interlayer insulating layer and the data output lines of the data connection lines,
the first planarization layer is on the passivation layer,
each of the second gate insulating layer, the interlayer insulating layer, and the passivation layer contains an inorganic insulating material,
the passivation layer is exposed through the at least one open groove, and
the data bridge line of each of the data connection lines is covered with the passivation layer and at least one of the second gate insulating layer or the interlayer insulating layer.

17. The electronic device of claim 13, wherein the main region comprises a display area in which emission areas are arranged, and a non-display area around the display area,
the data lines are in the display area,
each of the data connection lines further comprises a data supply line in the non-display area and electrically connected to the data bending line, and
the data supply lines of the data connection lines are electrically connected to the data lines.

18. The electronic device of claim 17, wherein the display device further comprises:
an element layer on the circuit layer;
an encapsulation layer covering the element layer; and
a touch sensor layer on the encapsulation layer,
wherein the element layer comprises:
first electrodes in the emission areas;
a pixel defining layer in a non-emission area between the emission areas and covering edges of the first electrodes;
light emitting layers on the first electrodes; and
a second electrode on the pixel defining layer and the light emitting layers, and
the touch sensor layer further comprises:
a touch buffer layer on the encapsulation layer;
a touch interlayer insulating layer covering a first touch conductive layer on the touch buffer layer; and
a touch planarization layer covering a second touch conductive layer on the touch interlayer insulating layer,
wherein the pixel defining layer extends to the sub-region, and
the at least one open groove is further formed in the pixel defining layer.

19. The electronic device of claim 17, wherein the display device further comprises: constant voltage connection lines in the open peripheral area, the bending area and the non-display area and configured to transmit a constant voltage,
wherein some of the data output lines of the data connection lines overlap the constant voltage connection lines in a thickness direction of the substrate.

20. The electronic device of claim 19, wherein the display device further comprises: dummy output lines between the data output lines,
wherein the dummy output lines are in the first source-drain conductive layer and spaced apart from the bending area and the at least one open area and overlap the constant voltage connection lines in the thickness direction of the substrate.
